(19) United States
(12) Patent Application Publication
(10) Pub. No.: US 2022/0199595 A1
(43) Pub. Date: Jun. 23, 2022

(54) INTEGRATED CIRCUIT PACKAGE HAVING A REDISTRIBUTION LAYER ABOVE A POWER MANAGEMENT INTEGRATED CIRCUIT

(71) Applicant: QUALCOMM Incorporated, San Diego, CA (US)

(72) Inventors: Aniket PATIL, San Diego, CA (US); Hong Bok WE, San Diego, CA (US)

(21) Appl. No.: 17/127,722

(22) Filed: Dec. 18, 2020

(51) Int. Cl. H01L 25/16; H01L 23/538; H01L 23/64; H01L 23/498; H01L 23/31; H01L 25/00

(52) U.S. Cl. CPC H01L 25/162; H01L 23/5385; H01L 23/5389; H01L 25/50; H01L 23/642; H01L 23/49816; H01L 23/3128; H01L 23/645

(57) ABSTRACT

A packaged assembly for integrated circuits having a redistribution layer (RDL) above a power management integrated circuit (PMIC) die for vertical connectivity from the PMIC die to another component of the packaged assembly (e.g., a wireless communication module) and techniques for fabrication thereof. An exemplary packaged assembly for integrated circuits includes: a first RDL; a second RDL disposed below the first RDL; a PMIC die disposed between the first RDL and the second RDL; a first passive component disposed adjacent to the PMIC die and between the first RDL and the second RDL; and a second passive component, wherein a first terminal of the second passive component is coupled to the PMIC die via the first RDL, and wherein a second terminal of the second passive component is coupled to the first passive component via the first RDL.

### BACKGROUND

### Field of the Disclosure

Aspects of the present disclosure relate to integrated circuits, and more particularly, to a compact integrated circuit (IC) package having a redistribution layer (RDL) above a power management integrated circuit (PMIC) die, and techniques for fabricating such a compact package.

### Description of Related Art

Electronic devices, such as computers, wireless communications devices (e.g., cellular phones and Wi-Fi access points), and wearable devices, have come into widespread use in recent years. The electronic devices typically include one or more integrated circuits (ICs). These ICs are typically included in one or more semiconductor dies and other electronic components, which may be included in an IC package for assembly on a printed circuit board (PCB) and included in an electronic device.

Packaging integrated circuit dies and other components together in modules (also referred to herein as “packaged assemblies”) may enable electronic devices to have a smaller form factor while providing improved signal performance (e.g., reduced transient signal leakage), electrical performance (e.g., reduced power consumption), and thermal performance (e.g., reduced heat generation), as compared to previously known electronic devices. For example, a smartphone may have improved battery life due to a reduction in power consumed by a transceiver module in which dies and other components are assembled in a packaged assembly.

### SUMMARY

The methods and assemblies of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include improved connectivity (e.g., shorter conductive paths with lower resistive loss) of power distribution networks (PDNs) in packaged assemblies.

Certain aspects of the present disclosure provide a packaged assembly for integrated circuits. The packaged assembly generally includes a first redistribution layer (RDL); a second RDL disposed below the first RDL; a power-management integrated circuit (PMIC) die disposed between the first RDL and the second RDL; a first passive component disposed adjacent to the PMIC die and between the first RDL and the second RDL; and a second passive component disposed above the first RDL, wherein a first terminal of the second passive component is coupled to the PMIC die via the first RDL, and wherein the second passive component is coupled to the first passive component via the first RDL.

Certain aspects of the present disclosure provide a method for fabricating a packaged assembly for integrated circuits. The method generally includes disposing a first passive component adjacent to a power management integrated circuit (PMIC) die; forming a first redistribution layer (RDL) above the PMIC die and the first passive component; disposing a second passive component above the first RDL, wherein a first terminal of the second passive component is coupled to the PMIC die via the first RDL and wherein a second terminal of the second passive component is coupled to the first passive component via the first RDL; and forming a second RDL below the PMIC die and the first passive component, such that the PMIC die and the first passive component are disposed between the first RDL and the second RDL.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device that includes a power management integrated circuit (PMIC), in which certain aspects of the present disclosure may be practiced.

FIGS. 2A and 2B are a cross-sectional view and a bottom view, respectively, of an exemplary packaged assembly.

FIG. 3 is a cross-sectional view of an exemplary packaged assembly having a redistribution layer (RDL) above a PMIC, in accordance with certain aspects of the present disclosure.

FIG. 4 is a flow diagram illustrating example operations for fabricating a packaged assembly for integrated circuits, in accordance with certain aspects of the present disclosure.

FIGS. 5A and 5B conceptually illustrate multiple overlaid layers, when viewed from above, of an example arrangement of a packaged assembly and a more compact packaged assembly, respectively, in accordance with certain aspects of the present disclosure.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

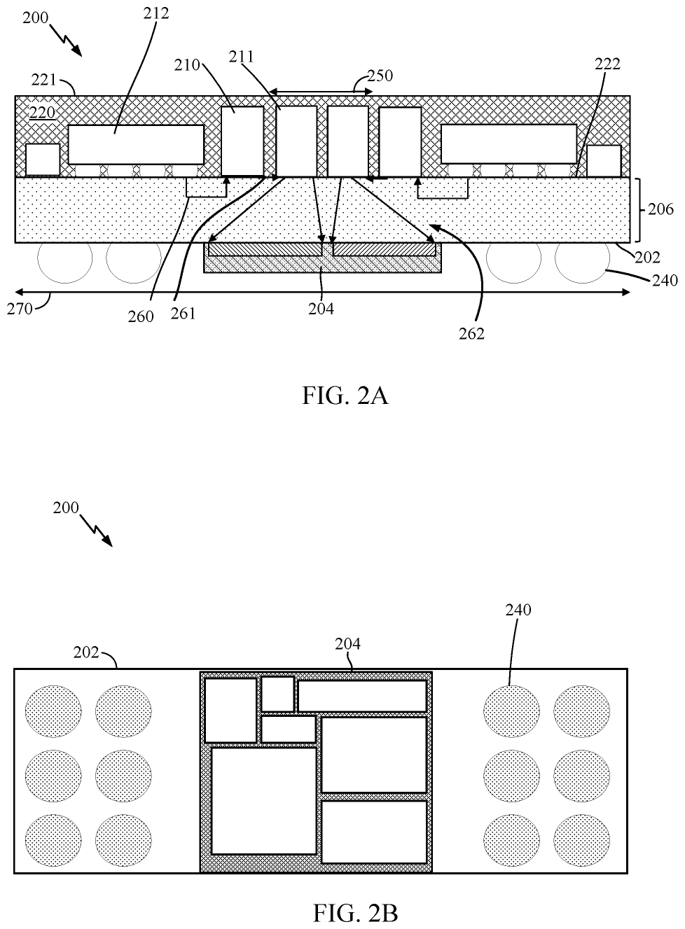

Aspects of the present disclosure provide a packaged assembly for integrated circuits (ICs) with a redistribution layer (RDL) above a power management integrated circuit (PMIC) die for vertical connectivity from the PMIC die to another component of the packaged assembly (e.g., a wireless communication module) and techniques for fabrication thereof. A “packaged assembly for integrated circuits” may also be referred to herein or otherwise as a “package,” “package for integrated circuits,” “integrated circuit package,” “chip package,” or “packaged assembly.” A “PMIC die” may also be referred to herein or otherwise as a “PMIC.” In aspects of the present disclosure, a packaged assembly for integrated circuits includes a first RDL, a second RDL disposed below the first RDL, a PMIC die disposed between the first RDL and the second RDL, a first passive component disposed adjacent to the PMIC die and between the first RDL and the second RDL, and a second passive component disposed above the first RDL and coupled to the PMIC die and the first passive component. The described packaged assembly may enable a conductive path from the PMIC die to the second passive component to be a vertical conductive path, and the vertical conductive path may be shorter than a (primarily lateral) conductive path in a package assembly utilizing a laminate substrate (see, e.g., FIG. 2A) or a packaged assembly having a single RDL below the PMIC die. In aspects of the present disclosure, in such a packaged assembly with a first RDL above a PMIC die, power from the second passive component (e.g., an inductor) may be conveyed vertically through the first RDL to the first passive component (e.g., a capacitor), and then vertically through the second RDL (e.g., similar to the RDL above the PMIC die) from the second passive component to an integrated circuit (IC) die of the packaged assembly. In such a packaged assembly, conveying the power vertically may shorten the path taken by the power (as compared to a package without an RDL above the PMIC die and/or with a more lateral component arrangement), which may reduce both resistive power losses and generation of transient signals associated with transmission of the power from the PMIC die through the passive components and to the IC die.

The following description provides examples of packaged assemblies having an RDL above a PMIC die, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

### Example Device

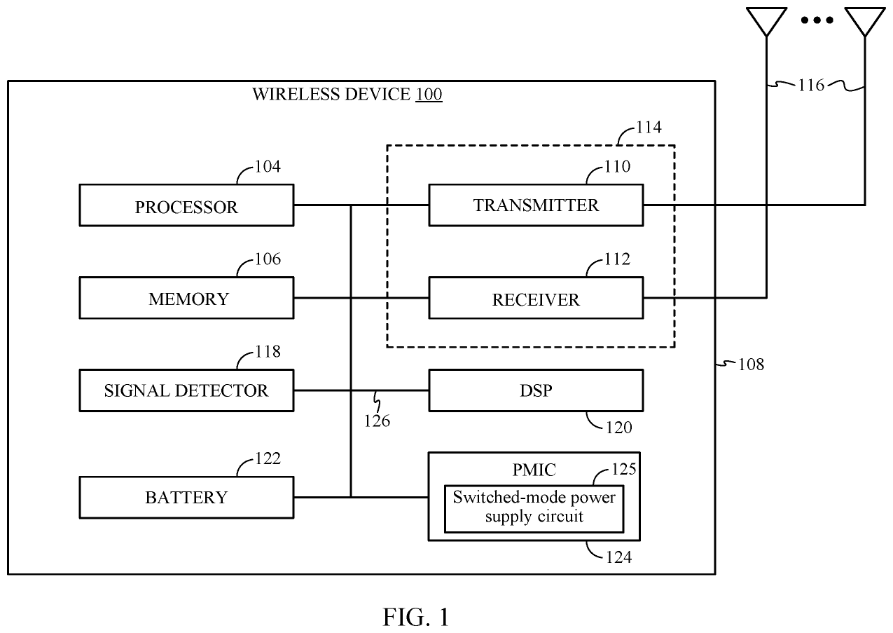

FIG. 1 illustrates an example device 100 in which aspects of the present disclosure may be implemented. The device 100 may be a battery-operated device such as a cellular phone, a personal digital assistant (PDA), a handheld device, a wireless device, a laptop computer, a tablet, a smartphone, a wearable device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122 used to power the various components of the device 100. The device 100 may also include a power management integrated circuit (PMIC) 124 for managing the power from the battery to the various components of the device 100. The PMIC 124 may perform a variety of functions for the device such as DC-to-DC conversion, battery charging, power-source selection, voltage scaling, power sequencing, etc. In certain aspects, the PMIC 124 may include at least a portion of a power supply circuit, which may include a switched-mode power supply circuit 125. The switched-mode power supply circuit 125 may be implemented by any of various suitable switched-mode power supply circuit topologies, such as a buck converter or a charge pump. For certain aspects, the PMIC 124 may include a battery charging circuit (e.g., a master-slave battery charging circuit). For certain aspects, one or more PMICs 124, one or more supporting power supply circuit components (e.g., external inductors and/or capacitors, and/or one or more (logic or other) integrated circuit dies may be combined in a packaged assembly, as described below.

The various components of the device 100 may be coupled together by a bus system 126, which may include a power bus, a control signal bus, and/or a status signal bus in addition to a data bus.

### Example Packaged Assembly with Lateral Connections

FIG. 2A is a cross-sectional view of an exemplary packaged assembly 200. FIG. 2B is a bottom view of the exemplary packaged assembly 200. The packaged assembly 200 includes a substrate 202 (e.g., a laminate substrate), at least one IC die 204 (with one or more logic blocks or areas), one or more power management integrated circuit (PMIC) dies 212, one or more first passive components 211 (e.g., capacitors or other passive components, such as a decoupling capacitor for a power rail connected to the IC die 204), one or more second passive components 210 (e.g., inductors or other passive components), and a first encapsulant 220 on the substrate 202. The first encapsulant 220 has a first surface 221 and a second surface 222 and may comprise resin or any of various other suitable materials. The packaged assembly 200 may optionally include pins for external connection, which may be implemented as a ball grid array (BGA) of solder balls 240. Additionally or alternatively, pins of the exemplary packaged assembly 200 may be a grid of contacts in a land grid array (LGA) or groups of leads along the periphery of the package in a small outline package (SOP) arrangement, instead of the illustrated BGA.

Power from the PMIC 212 to the second passive component 210 may be provided through an interconnection 260, which may primarily be a lateral conductive path. For example, the second passive component 210 may be an inductor of a switched-mode power supply circuit (e.g., a buck converter), a portion of which is included in the PMIC die 212. The interconnection 260 may include multiple vias and a trace routed in a layer of the substrate 202. Power from the second passive component 210 to the first passive component 211 (e.g., a three-terminal (3T) capacitor) may be provided through an interconnection 261. As another lateral conductive path, the interconnection 261 may include a trace routed on the surface of the substrate 202. Interconnections 262 convey power from the first passive components 211 to the IC die 204. An area (e.g., a footprint) illustrated by line 250 is available for power distribution network (PDN) components, such as first passive components 211. A lateral form factor of the packaged assembly 200 is represented by line 270.

Because the PMIC die 212 and the second passive component 210 cannot occupy the same location, the interconnection 260 cannot be shorter than the size of a lateral gap between the PMIC die 212 and the second passive component 210 in this lateral component arrangement. Similarly, the interconnection 261 cannot be shorter than the size of a lateral gap between the second passive component 210 and the first passive component 211 in this lateral component arrangement. If the interconnection 260 includes a vertical component (e.g., using a via in the substrate 202), as illustrated, then the interconnection may be longer than the lateral gap between the PMIC die 212 and the second passive component 210. Similarly, if the interconnection 261 has a vertical component, then the interconnection 261 may be longer than the lateral gap between the second passive component 210 and the first passive component 211. The lengths of the interconnections 260 and 261 affect the resistance of those interconnections, with longer interconnections having higher resistance that reduces power efficiency of the packaged assembly 200. The substrate 202 may include several layers, with traces routed on each of the layers and vias providing vertical connectivity between traces of the different layers, the PMIC dies 212, first passive components 211, second passive components 210, IC die 204, and/or solder balls 240. The number of layers of the substrate is related to the number of connections involved between the PMIC dies 212, first passive components 211, second passive components 210, IC die 204, and/or solder balls 240, as connections that cross each other laterally are typically placed on different layers so that the connections are electrically isolated from each other. The number of layers of the substrate is directly related to the thickness 206 of the substrate. The thickness 206 of the substrate affects the length of the interconnections 262 from the first passive components 211 to the IC die 204. As with the interconnections 260 and 261, the longer the interconnections 262 are, the higher the electrical resistances of those interconnections are.

### Example Integrated Circuit Package Having a Redistribution Layer Above a Power Management Integrated Circuit

Aspects of the present disclosure provide a compact redistribution layer (RDL) package for integrated circuits and techniques for fabricating such a package. The compact RDL package has a redistribution layer above a power management integrated circuit (PMIC) for vertical connectivity from the PMIC to another component of the package, among other features.

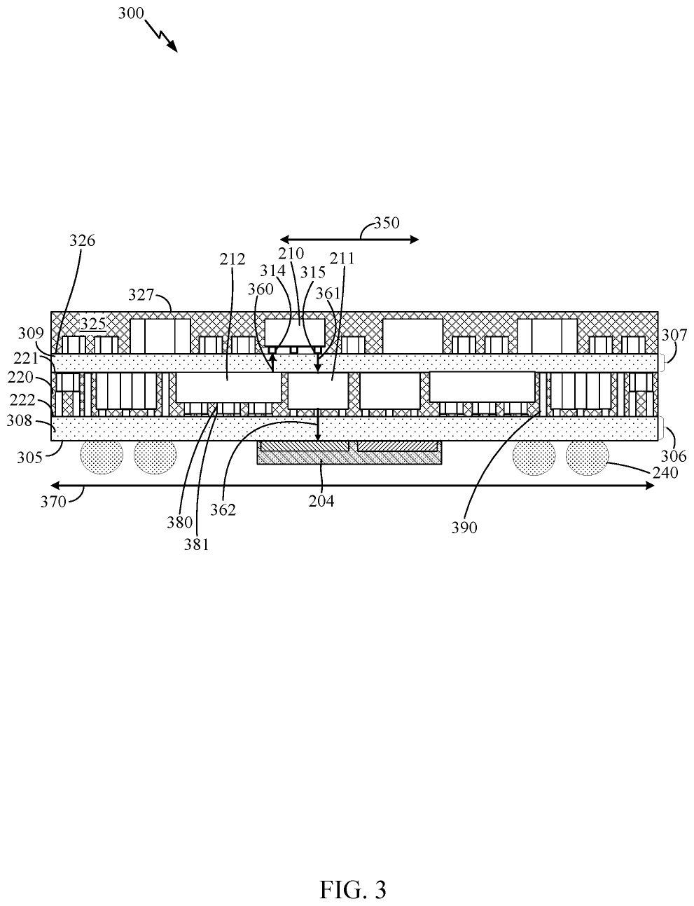

FIG. 3 is a cross-sectional view of an exemplary packaged assembly 300, in accordance with certain aspects of the present disclosure. The packaged assembly 300 includes at least one IC die 204 (e.g., an application processor die), one or more PMIC dies 212, one or more first passive components 211 (e.g., capacitors or other passive components), one or more second passive components 210 (e.g., inductors or other passive components), a first encapsulant 220, and optionally pins implemented as a ball grid array (BGA) of solder balls 240, which were described above with reference to FIG. 2A. The packaged assembly 300 also includes a first redistribution layer (RDL) 309 and a second RDL 308. A bottom surface 305 of the second RDL may include contacts to pins of the packaged assembly 300 (e.g., the solder balls 240). Additionally or alternatively, pins of the exemplary packaged assembly 300 may be a grid of contacts in a land grid array (LGA) or groups of leads along the periphery of the package in a small outline package (SOP) arrangement, instead of the illustrated BGA of solder balls 240. A second encapsulant 325 (which may be composed of the same type of encapsulant material as the first encapsulant 220) is over (e.g., the second encapsulant is applied over) the second passive components 210 and the first RDL 309. The second encapsulant 325 has a first surface 326 (a bottom surface) and a second surface 327 (a top surface).

Power from the PMIC die 212 to a first terminal 314 of the second passive component 210 may be provided through an interconnection 360, which may completely or primarily be a vertical conductive path. As another at least primarily vertical conductive path, interconnection 361 conveys power through the first RDL 309 from a second terminal 315 of the second passive component 210 to the first passive component 211 (e.g., to a terminal (not shown) that spans the height of the component 211). As still another vertical conductive path, one or more interconnections 362 convey power through the second RDL 308 from the first passive component 211 to the IC die 204. An area (e.g., a footprint) illustrated by line 350 is available for PDN components, such as first passive components 211. A lateral form factor of the packaged assembly 300 is represented by line 370.

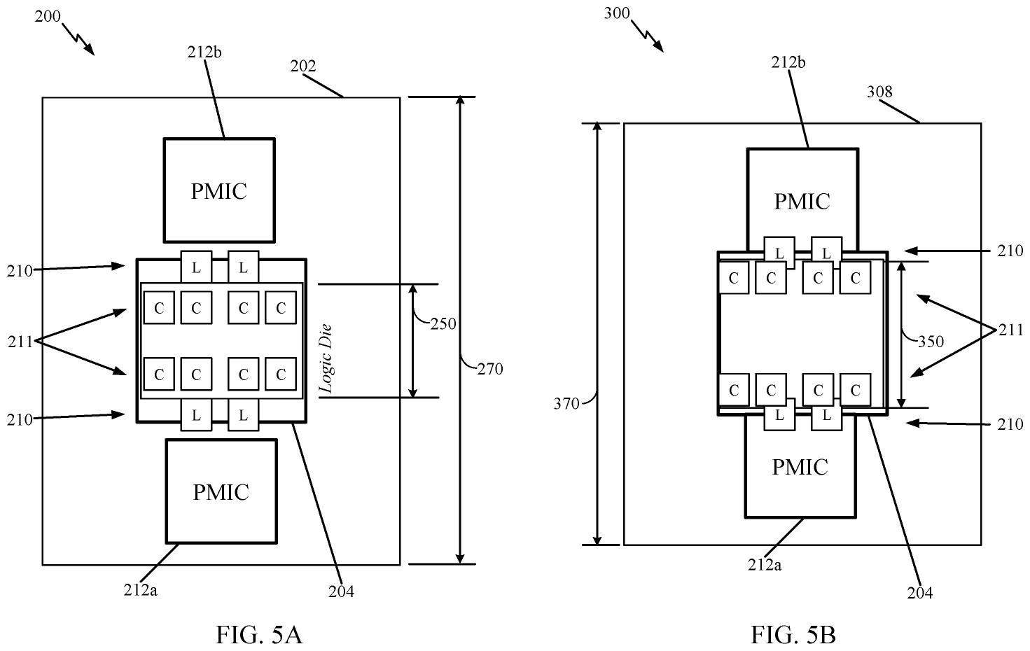

Because the second passive component 210 partially overlaps the PMIC die 212 (that is, the second passive component 210 is disposed above the PMIC die 212 in the packaged assembly 300 and a perimeter of the second passive component 210 intersects a perimeter of the PMIC die 212, as shown in FIG. 5B), the interconnection 360 is primarily vertical. Because a thickness 307 of the first RDL 309 may be smaller than the size of a lateral gap between the PMIC die 212 and the second passive component 210 shown in FIG. 2A, the interconnection 360 may be shorter than the interconnection 260. Similarly, because the second passive component 210 partially overlaps the first passive component 211 (that is, the second passive component 210 is disposed above the first passive component 211 in the packaged assembly 300 and a perimeter of the second passive component 210 intersects a perimeter of the first passive component 211, as shown in FIG. 5B), the interconnection 361 is primarily vertical and can be shorter than the interconnection 261. The lengths of the interconnections 360 and 361 affect the resistance of those interconnections, and thus the interconnections 360 and 361 may have lower resistances than the interconnections 260 and 261. For example, a primarily lateral interconnection (e.g., interconnection 260 in FIG. 2A) from a PMIC die (e.g., PMIC die 212 in FIG. 2A) to a passive component (e.g., second passive component 210 in FIG. 2A) may have a conductive connection length of about 0.5 mm, while a primarily vertical interconnection (e.g., interconnection 360 in FIG. 3) from a PMIC die (e.g., PMIC die 212 in FIG. 3) to a passive component (e.g., second passive component 210 in FIG. 3) may have a conductive connection length of about 50 μm.

The second RDL 308 may include several layers, with traces routed on each of the layers and vias providing vertical connectivity between traces of the different layers, the PMIC dies 212, first passive components 211, IC die 204, and/or solder balls 240. As the interconnections 360 and 361 between the PMIC dies 212, second passive components 210, and first passive components 211 are in the first RDL 309, fewer interconnections are made within the second RDL 308 than are made within the substrate 202. Thus, the second RDL 308 may have fewer layers than the substrate 202, and the thickness 306 of the second RDL 308 may be smaller than the thickness 206 of the substrate 202. Because the thickness 306 of the second RDL 308 affects the length of the interconnections 362 from the first passive components 211 to the IC die 204, the interconnections 362 may be shorter and have lower electrical resistance than the interconnections 262. For example, in a packaged assembly having primarily lateral interconnections (e.g., packaged assembly 200 in FIG. 2A), an interconnection length from a passive component (e.g., second passive component 210 in FIG. 2A) through another passive component (e.g., first passive component 211 in FIG. 2A) and to an IC die (e.g., IC die 204 in FIG. 2A) may be more than 2 mm long, while, in a packaged assembly having primarily vertical interconnections (e.g., packaged assembly 300 in FIG. 3), an interconnection length from a passive component (e.g., second passive component 210 in FIG. 3) through another passive component (e.g., first passive component 211 in FIG. 3) and to an IC die (e.g., IC die 204 in FIG. 3) may be less than 1 mm long.

In aspects of the present disclosure, the first terminal 314 of the second passive component 210 may be coupled to a peripheral pin of the PMIC die 212. Using a peripheral pin of the PMIC die 212 may assist in providing a vertical conductive path for the interconnection 360.

In aspects of the present disclosure, the packaged assembly 300 may include a third passive component 380 disposed between the PMIC die 212 and the second RDL 308. In this case, at least one terminal 381 of the third passive component 380 may be coupled to the second RDL 308. In certain aspects, the same or a different terminal of the third passive component 380 is coupled the PMIC die 212.

### Example Operations for Fabricating a Compact RDL Package

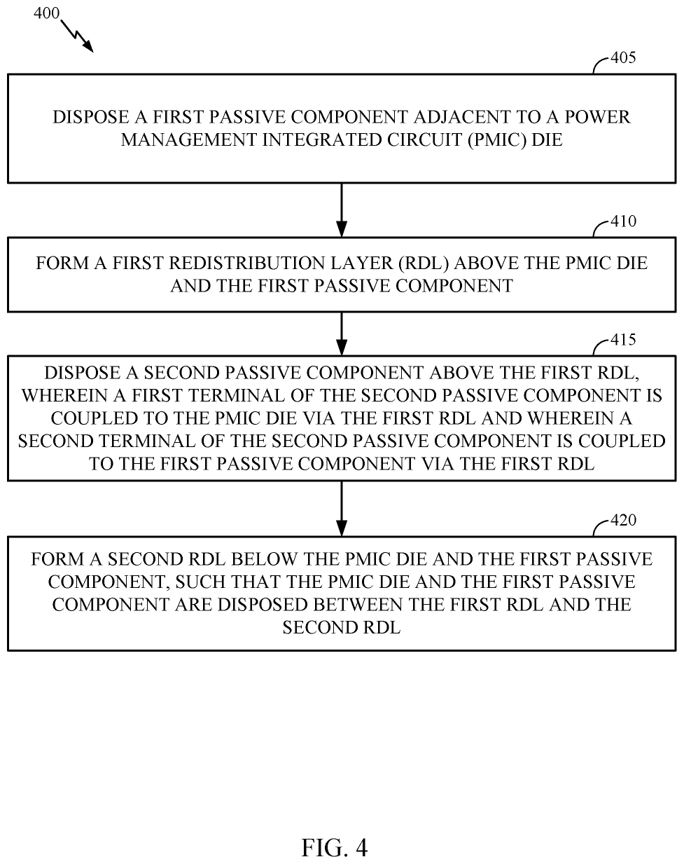

FIG. 4 is a flow diagram illustrating example operations 400 for fabricating a packaged assembly for integrated circuits (e.g., packaged assembly 300), in accordance with certain aspects of the present disclosure. The operations 400 may be performed, for example, by an integrated circuit packaging facility.

The operations 400 may begin, at block 405, by disposing a first passive component (e.g., first passive component 211) adjacent to a power management integrated circuit (PMIC) die (e.g., PMIC die 212).

The operations 400 continue, at block 410, by forming a first redistribution layer (e.g., RDL 309, described above with reference to FIG. 3) above the PMIC die and the first passive component.

The operations 400 continue, at block 415, by disposing a second passive component (e.g., second passive component 210) above the first RDL, wherein a first terminal (e.g., first terminal 314, described above with reference to FIG. 3) of the second passive component is coupled to the PMIC die via the first RDL and wherein a second terminal (e.g., second terminal 315, described above with reference to FIG. 3) of the second passive component is coupled to the first passive component via the first RDL.

The operations 400 continue, at block 420, by forming a second RDL (e.g., the second RDL 308, described above with reference to FIG. 3) below the PMIC die and the first passive component, such that the PMIC die and the first passive component are disposed between the first RDL and the second RDL.

According to aspects of the present disclosure, disposing the first passive component adjacent to the PMIC die as in block 405 may optionally include disposing the PMIC die and the first passive component on a first carrier plate; applying a first encapsulant (e.g., first encapsulant 220, described above with reference to FIG. 3) over the PMIC die and the first passive component; attaching a second carrier plate to the first encapsulant subsequent to applying the first encapsulant and prior to forming the first RDL as in block 410; and removing the first carrier plate from the first encapsulant subsequent to applying the first encapsulant and prior to forming the first RDL as in block 410. In some such aspects, the operations 400 may optionally further include removing the second carrier plate from the first encapsulant subsequent to applying a second encapsulant (e.g., second encapsulant 325, described above with reference to FIG. 3) over the first RDL and the second passive component; and attaching a third carrier plate to the second encapsulant prior to forming the second RDL as in block 420. In some such aspects, the operations 400 may optionally include grinding a surface of the first encapsulant prior to forming the second RDL as in block 420.

In aspects of the present disclosure, the operations 400 may optionally include attaching a plurality of solder balls (e.g., solder balls 240) implemented as a BGA to the second RDL such that the PMIC die is conductively connected with at least one of the plurality of solder balls.

FIG. 5A conceptually illustrates an example arrangement of components in multiple overlaid layers, when viewed from above, of the packaged assembly 200. In the example arrangement of packaged assembly 200, two PMIC dies 212a and 212b (collectively, “PMIC dies 212”) are disposed above a substrate 202. First passive components 211 (e.g., capacitors) and second passive components 210 (e.g., inductors) are also disposed above the substrate 202. An IC die 204 disposed below the substrate 202 is also shown. An area (e.g., a footprint) illustrated by line 250 is available for PDN connections from the first passive components 211 to the IC die 204.

FIG. 5B conceptually illustrates an example arrangement of components in multiple overlaid layers, when viewed from above, of the packaged assembly 300, in accordance with certain aspects of the present disclosure. In the example arrangement of packaged assembly 300, two PMIC dies 212 are disposed above a second RDL 308. First passive components 211 (e.g., capacitors) are also disposed above the second RDL 308. Disposed above a first RDL (not shown in FIG. 5B, but described above with reference to FIG. 3), second passive components 210 (e.g., inductors) are disposed above and partially overlap the PMIC dies 212 and partially overlap the first passive components 211. An IC die 204 is also disposed below the second RDL 308. An area (e.g., a footprint) illustrated by line 350 is available for PDN connections from the first passive components 211 to the IC die 204 in packaged assembly 300.

As illustrated, the packaged assembly 300, which has an RDL above a PMIC die, has a smaller lateral form factor (illustrated by line 370) than the lateral form factor (illustrated by line 270 in FIG. 5A) of the packaged assembly 200. Also as illustrated, the packaged assembly 300 has a larger area (e.g., a footprint, illustrated by line 350 in FIG. 5B) available for PDN connections from the first passive components 211 to the IC die 204 than the area (illustrated by line 250 in FIG. 5A) available for PDN connections from the first passive components 211 to the IC die 204 of the packaged assembly 200.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

The various operations of methods described above may be performed by any suitable means capable of performing the corresponding functions. Generally, where there are operations illustrated in figures, those operations may have corresponding counterpart means-plus-function components with similar numbering.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A packaged assembly for integrated circuits, comprising:
a first redistribution layer (RDL);
a second RDL disposed below the first RDL;
a power-management integrated circuit (PMIC) die disposed between the first RDL and the second RDL;
a first passive component disposed adjacent to the PMIC die and between the first RDL and the second RDL; and
a second passive component disposed above the first RDL, wherein a first terminal of the second passive component is coupled to the PMIC die via the first RDL, and wherein a second terminal of the second passive component is coupled to the first passive component via the first RDL.

2. The packaged assembly of claim 1, wherein the second passive component at least partially overlaps the PMIC die.

3. The packaged assembly of claim 2, wherein the second passive component partially overlaps the first passive component.

4. The packaged assembly of claim 1, wherein the second passive component at least partially overlaps the first passive component.

5. The packaged assembly of claim 1, wherein a conductive path from the first terminal of the second passive component to the PMIC die is a vertical conductive path.

6. The packaged assembly of claim 1, wherein the first terminal of the second passive component is coupled to a peripheral pin of the PMIC die.

7. The packaged assembly of claim 1, wherein the second passive component comprises an inductor.

8. The packaged assembly of claim 7, wherein the first passive component comprises a capacitor.

9. The packaged assembly of claim 8, wherein the inductor is part of a switched-mode power supply circuit of the PMIC die.

10. The packaged assembly of claim 1, further comprising an integrated circuit (IC) die, wherein the IC die is coupled to the first passive component via the second RDL.

11. The packaged assembly of claim 10, wherein the first passive component comprises a decoupling capacitor for the IC die.

12. The packaged assembly of claim 10, wherein an interconnection length between the second terminal of the second passive component and the IC die through the first passive component is less than 1 millimeter (mm).

13. The packaged assembly of claim 1, wherein a first conductive path from the second terminal of the second passive component to the first passive component is a vertical conductive path.

14. The packaged assembly of claim 13, further comprising an integrated circuit (IC) die, wherein the IC die is coupled to the first passive component via the second RDL and wherein a second conductive path from the first passive component to the IC die is another vertical conductive path.

15. The packaged assembly of claim 1, further comprising a plurality of solder balls implemented as a ball grid array (BGA) and disposed adjacent to a bottom surface of the second RDL, wherein the PMIC die is connected to at least one of the solder balls via the second RDL.

16. The packaged assembly of claim 1, further comprising at least one third passive component disposed between the PMIC die and the second RDL, wherein at least one terminal of the third passive component is coupled to the second RDL.

17. The packaged assembly of claim 1, further comprising a first encapsulant disposed between the PMIC and the first passive component and disposed between the first RDL and the second RDL.

18. The packaged assembly of claim 17, further comprising a second encapsulant disposed above at least one of the second passive component or the first RDL.

19. The packaged assembly of claim 1, wherein a conductive connection length from the first terminal of the second passive component to the PMIC die is about 50 micrometers (μm).

20. A method for fabricating a packaged assembly for integrated circuits, the method comprising:
disposing a first passive component adjacent to a power management integrated circuit (PMIC) die;
forming a first redistribution layer (RDL) above the PMIC die and the first passive component;
disposing a second passive component above the first RDL, wherein a first terminal of the second passive component is coupled to the PMIC die via the first RDL and wherein a second terminal of the second passive component is coupled to the first passive component via the first RDL; and
forming a second RDL below the PMIC die and the first passive component, such that the PMIC die and the first passive component are disposed between the first RDL and the second RDL.
